(19) United States
(12) Patent Application Publication
(10) Pub. No.: US 2025/0204206 A1
(43) Pub. Date: Jun. 19, 2025

(54) DISPLAY DEVICE AND METHOD OF MANUFACTURING THE SAME

(71) Applicant: Samsung Display Co., LTD., Yongin-si (KR)

(72) Inventors: Ki Nyeng KANG, Yongin-si (KR); Guang Hai JIN, Yongin-si (KR); Sun Kwang KIM, Yongin-si (KR); Jong Hwan CHA, Yongin-si (KR)

(73) Assignee: Samsung Display Co., LTD., Yongin-si (KR)

(21) Appl. No.: 18/921,414

(22) Filed: Oct. 21, 2024

(30) Foreign Application Priority Data
Dec. 18, 2023 (KR) 10-2023-0184949

(51) Int. Cl. H10K 59/80; H10K 59/12; H10K 59/122

(52) U.S. Cl. CPC H10K 59/80522; H10K 59/1201; H10K 59/122

(57) ABSTRACT

A display device includes a substrate including a display area including sub-pixels, and a non-display area adjacent to the display area, a first electrode disposed on the substrate, a second electrode disposed on the substrate, a light emitting structure disposed on the first electrode and the second electrode in the display area, and a third electrode disposed on the light emitting structure in the display area and disposed on the second electrode in at least a portion of the non-display area.

### CROSS-REFERENCE TO RELATED APPLICATION(S)

This application claims priority to and benefits of Korean Patent Application No. 10-2023-0184949 under 35 U.S.C. § 119, filed on Dec. 18, 2023 in the Korean Intellectual Property Office (KIPO), the entire contents of which are herein incorporated by reference.

### BACKGROUND

### 1. Technical Field

The disclosure relates to a display device and a method of manufacturing the same.

### 2. Description of the Related Art

As information technology develops, the importance of a display device, which is a connection medium between a user and information, is emerging. In response, use of a display device such as a liquid crystal display device and an organic light emitting display device is increasing.

Recently, head mounted display (HMDs) devices are being developed. HMDs are display devices that implement virtual reality (VR) or augmented reality (AR) in which a user wears an HMD in a form of glasses or a helmet and a focus is formed at a distance close to the user's eyes. A high-resolution panel may be applied to an HMD, and thus a pixel applicable to the high-resolution panel is desirable.

### SUMMARY

An aspect of the disclosure is to provide a display device that reduces a leakage current.

Another aspect of the disclosure is to provide a method of manufacturing a display device.

In order to achieve an aspect of the disclosure, a display device may include a substrate including a display area including sub-pixels, and a non-display area adjacent to the display area, a first electrode disposed on the substrate, a second electrode disposed on the substrate, a light emitting structure disposed on the first electrode and the second electrode in the display area, and a third electrode disposed on the light emitting structure in the display area and disposed on the second electrode in at least a portion of the non-display area.

In an embodiment, the third electrode may electrically contact the second electrode in the at least the portion of the non-display area.

In an embodiment, the third electrode may be electrically connected to the first electrode in the at least the portion of the non-display area.

In an embodiment, the third electrode may be electrically connected to a conductive pattern disposed under the first electrode in the at least the portion of the non-display area.

In an embodiment, the display device may further include an insulating layer disposed on the first electrode and including an opening exposing at least a portion of the first electrode, and the second electrode may be disposed on the insulating layer.

In an embodiment, the third electrode may extend to the insulating layer in the at least the portion of the non-display area.

In an embodiment, the light emitting structure may fill the opening, and the light emitting structure may be entirely disposed on the insulating layer in the display area.

In an embodiment, the light emitting structure may include a first light emitting unit, a second light emitting unit disposed on the first light emitting unit, and a connection layer disposed between the first light emitting unit and the second light emitting unit and electrically connecting the first light emitting unit and the second light emitting unit.

In an embodiment, a voltage applied to the second electrode may be less than a voltage of the first electrode at a lowest grayscale.

In an embodiment, the second electrode may be disposed in a boundary area between at least two of the sub-pixels, and the at least two of the sub-pixels may be adjacent to each other.

In order to achieve an aspect of the disclosure, a method of manufacturing a display device may include providing a substrate including a display area including sub-pixels, and a non-display area disposed adjacent to the display area, forming a first electrode on the substrate, applying an insulating layer to cover the first electrode, forming a second electrode on the insulating layer, exposing at least a portion of the first electrode by patterning the insulating layer, forming a light emitting structure on the first electrode and the second electrode in the display area, and forming a third electrode on the light emitting structure.

In an embodiment, the third electrode may be formed on the second electrode in at least a portion of the non-display area.

In an embodiment, the third electrode may electrically contact the second electrode in the at least the portion of the non-display area.

In an embodiment, the third electrode may be electrically connected to the first electrode in the at least the portion of the non-display area.

In an embodiment, the third electrode may be electrically connected to a conductive pattern disposed under the first electrode in the at least the portion of the non-display area.

In an embodiment, the third electrode may be formed on the light emitting structure in the display area and disposed on the insulating layer in the at least the portion of the non-display area.

In an embodiment, the light emitting structure may fill an opening of the insulating layer exposing the at least the portion of the first electrode, and the light emitting structure may be entirely disposed on the insulating layer in the display area.

In an embodiment, the light emitting structure may include a first light emitting unit, a second light emitting unit disposed on the first light emitting unit, and a connection layer disposed between the first light emitting unit and the second light emitting unit and electrically connecting the first light emitting unit and the second light emitting unit.

In an embodiment, a voltage applied to the second electrode may be less than a voltage of the first electrode at a lowest grayscale.

In an embodiment, the second electrode may be disposed in a boundary area between at least two of the sub-pixels, and the at least two of the sub-pixels may be adjacent to each other.

A display device according to embodiments of the disclosure may reduce a leakage current flowing between neighboring sub-pixels by forming a current path through which the leakage current may flow through a leakage electrode.

A display device according to embodiments of the disclosure may reduce noise due to coupling between sub-pixels adjacent to each other by forming a leakage electrode in a boundary area between the sub-pixels and applying a constant voltage to the leakage electrode.

A method of manufacturing a display device according to embodiments of the disclosure may reduce the number of contact holes and masks used in a process by connecting a cathode electrode to an anode electrode or a conductive pattern in an area where a light emitting structure is not formed.

However, effects of the disclosure are not limited to the effects described above, and may be variously expanded without departing from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating an embodiment of a display device;

FIG. 2 is a schematic block diagram illustrating an embodiment of any one of sub-pixels of FIG. 1;

FIG. 3 is a schematic plan view illustrating an embodiment of a display panel of FIG. 1;

FIG. 4 is an exploded schematic perspective view illustrating a portion of the display panel of FIG. 3;

FIG. 5 is a schematic plan view illustrating an embodiment of pixels of FIG. 4;

FIG. 6 is a schematic cross-sectional view taken along line I-I′ of FIG. 5;

FIG. 7 is a schematic cross-sectional view illustrating an embodiment of a light emitting structure included in any one of first to third light emitting elements of FIG. 6;

FIG. 8 is a schematic cross-sectional view illustrating another embodiment of the light emitting structure included in any one of the first to third light emitting elements of FIG. 6;

FIG. 9 is a schematic plan view illustrating another embodiment of any one of the pixels of FIG. 4;

FIG. 10 is a schematic plan view illustrating still another embodiment of any one of the pixels of FIG. 4;

FIG. 11 is a flowchart illustrating a method of manufacturing a display device according to embodiments of the disclosure;

FIG. 12 is a schematic diagram illustrating step S200 of FIG. 11;

FIG. 13 is a schematic diagram illustrating step S300 of FIG. 11;

FIG. 14 is a schematic diagram illustrating step S400 of FIG. 11;

FIG. 15 is a schematic diagram illustrating step S500 of FIG. 11;

FIG. 16 is a schematic diagram illustrating step S600 of FIG. 11;

FIG. 17 is a schematic diagram illustrating step S700 of FIG. 11;

FIG. 18 is a schematic cross-sectional view of a portion of a display device according to embodiments of the disclosure;

FIG. 19 is a schematic diagram of a circuit illustrating the first and second light emitting elements and a leakage element of FIG. 6;

FIG. 20 is a schematic diagram of a circuit illustrating a leakage current;

FIG. 21 is a schematic cross-sectional view of a display device according to embodiments of the disclosure;

FIG. 22 is a schematic block diagram illustrating an embodiment of a display system;

FIG. 23 is a schematic perspective view illustrating an application example of the display system of FIG. 22; and

FIG. 24 is a schematic diagram illustrating a head mounted display device worn by a user.

### DETAILED DESCRIPTION OF THE EMBODIMENTS

Hereinafter, embodiments according to the disclosure are described in detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiments described herein. However, the embodiments described herein are provided to describe in detail enough to readily implement the technical spirit of the disclosure to those skilled in the art to which the disclosure belongs.

As used herein, the singular forms, “a,” “an,” and “the” are intended to include the plural forms as well, unless the context clearly indicates otherwise.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XY, YZ, and XZ). Here, “and/or” includes all combinations of one or more of corresponding configurations. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Here, terms such as “first” and “second” may be used to describe various components, but these components are not limited to these terms. These terms are used to distinguish one component from another component. Therefore, a first component may refer to a second component without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and embodiments are not limited thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

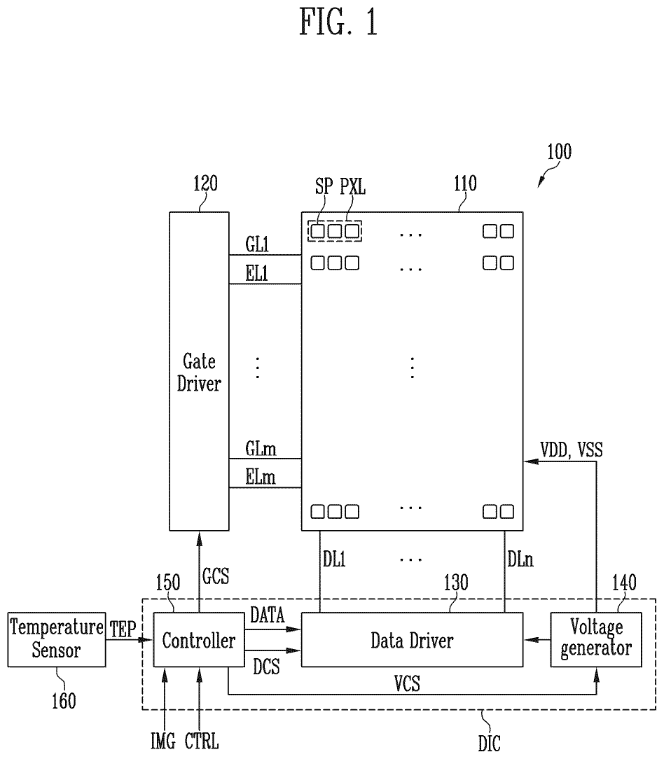

FIG. 1 is a schematic block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn. m and n are each integers greater than 0.

Each of the sub-pixels SP may include at least one light emitting element configured to generate light. Accordingly, each of the sub-pixels SP may generate light of a specific color such as red, green, blue, cyan, magenta, or yellow. Two or more sub-pixels SP among the sub-pixels SP may configure one pixel PXL. For example, as shown in FIG. 1, three sub-pixels SP may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm connected to the sub-pixels SP of the row direction may be further provided. The gate driver 120 may include an emission control driver configured to control the first to m-th emission control lines EL1 to ELm, and the emission control driver may operate under control of the controller 150.

The gate driver 120 may be disposed on one side of the display panel 110. However, embodiments are not limited thereto. For example, the gate driver 120 may be divided into two or more physically and/or logically divided drivers, and such drivers may be disposed on one side of the display panel 110 and another side of the display panel 110 opposite the one side. As described above, the gate driver 120 may be disposed around the display panel 110 in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. In case that the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device 100. For example, the voltage generator 140 may be configured to generate the voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. In other embodiments, the first power voltage VDD or the second power voltage VSS may be provided by an external device of the display device 100.

The voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined or selected reference voltage may be applied to the first to n-th data lines DL1 to DLn, and the voltage generator 140 may generate such a reference voltage.

The controller 150 may control overall operations of the display device 100. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature around the temperature sensor 160 and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

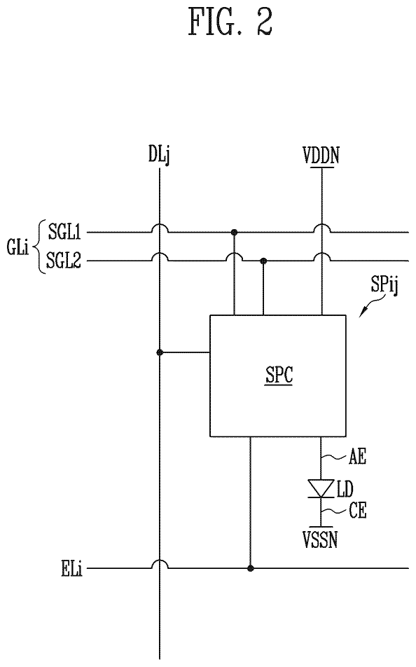

FIG. 2 is a schematic block diagram illustrating an example of any one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node that transfers the first power voltage VDD of FIG. 1, and the second power voltage node VSSN may be a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through such signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, in case that the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In case that the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light emitting element LD according to the stored voltage, in response to the emission control signal received through the i-th emission control line ELi. Accordingly, the light emitting element LD may generate light of a luminance corresponding to the data signal.

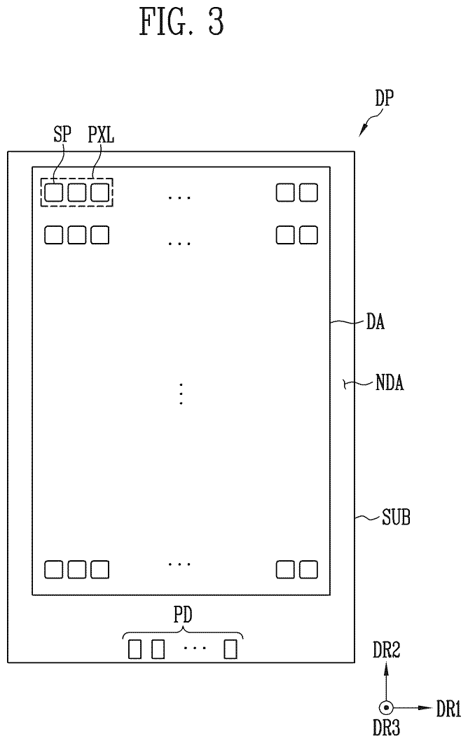

FIG. 3 is a schematic plan view illustrating an embodiment of the display panel of FIG. 1.

Referring to FIG. 3, an embodiment DP of the display panel 110 of FIG. 1 may include a display area DA and a non-display area NDA. The display panel DP may display an image through the display area DA. The non-display area NDA may be disposed around the display area DA.

The display panel DP may include a substrate SUB, the sub-pixels SP, and pads PD.

In case that the display panel DP is used as a display screen of a head mounted display (HMD) device, a virtual reality (VR) device, a mixed reality (MR) device, an augmented reality (AR) device, or the like, the display panel DP may be positioned very close to user's eyes. Sub-pixels SP of a relatively high integration degree are desirable. In order to increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDOS) display device.

The sub-pixels SP may be disposed in the display area DA on the substrate SUB. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

Two or more sub-pixels SP among the sub-pixels SP may configure one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and may be disposed in the non-display area NDA. In other embodiments, the gate driver 120 may be implemented as an integrated circuit separated from the display panel DP. In embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). In embodiments, voltages and signals for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member such as an anisotropic conductive film. The circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes such as a polygon, a circle, a semicircle, and an ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials having a flexible property.

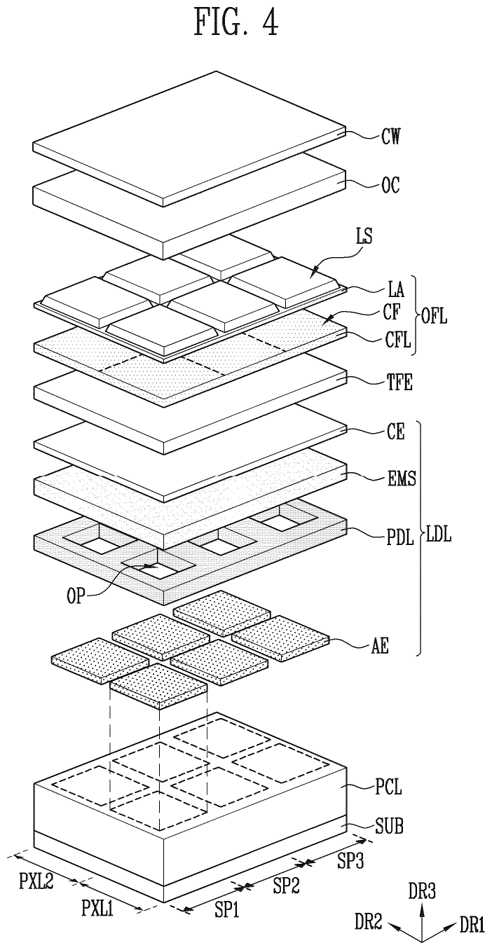

FIG. 4 is an exploded schematic perspective view illustrating a portion of the display panel of FIG. 3. In FIG. 4, for clear and concise description, a portion of the display panel DP corresponding to two pixels PXL1 and PXL2 among the pixels PXL of FIG. 3 is schematically shown. A portion of the display panel DP corresponding to remaining pixels may be similarly configured.

Referring to FIGS. 3 and 4, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 4, the first to third sub-pixels SP1, SP2, and SP3 have quadrangle shapes when viewed from a third direction DR3 crossing the first and second directions DR1 and DR2, and have sizes equal to each other. However, embodiments are not limited thereto. The first to third sub-pixels SP1, SP2, and SP3 may be modified to have various shapes.

The display panel DP may include the substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, lines, and the like. The conductive patterns may include copper, but embodiments are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, in case that the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, in case that the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer between the electrodes.

The lines of the pixel circuit layer PCL may include signal lines connected to each of the first to third sub-pixels SP1, SP2, and SP3, for example, a gate line, an emission control line, a data line, and the like. The lines may further include a line connected to the first power voltage node VDDN of FIG. 2. The lines may further include a line connected to the second power voltage node VSSN of FIG. 2.

The light emitting element layer LDL may include the anode electrodes AE, a pixel defining layer PDL, a light emitting structure EMS, and the cathode electrode CE.

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but embodiments are not limited thereto.

The pixel defining layer PDL may include an opening OP exposing a portion of each of the anode electrodes AE. The opening OP of the pixel defining layer PDL may be understood as emission areas corresponding to the first to third sub-pixels SP1 to SP3, respectively.

In an embodiment, the pixel defining layer PDL may expose a portion of each of the anode electrodes AE, but the disclosure is not limited thereto. For example, the pixel defining layer PDL may expose the entirety of each of the anode electrodes AE, and a portion where the pixel defining layer PDL and the anode electrodes AE overlap may not exist.

In embodiments, the pixel defining layer PDL may include an inorganic material. The pixel defining layer PDL may include inorganic layers stacked on each other. For example, the pixel defining layer PDL may include silicon oxide SiOx and silicon nitride SiNx. In other embodiments, the pixel defining layer PDL may include an organic material. However, a material of the pixel defining layer PDL is not limited thereto.

The light emitting structure EMS may be disposed on the anode electrodes AE exposed by the opening OP of the pixel defining layer PDL. The light emitting structure EMS may include a light emitting layer configured to generate light, an electron transport layer configured to transport an electron, a hole transport layer configured to transport a hole, and the like.

In embodiments, the light emitting structure EMS may fill the opening OP of the pixel defining layer PDL, and may be entirely disposed on the pixel defining layer PDL. In other words, the light emitting structure EMS may extend across the first to third sub-pixels SP1 to SP3. At least a portion of layers in the light emitting structure EMS may be disconnected or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and a mixture thereof. However, a material of the cathode electrode CE is not limited thereto.

It may be understood that any one of the anode electrodes AE, a portion of the light emitting structure EMS overlapping it, and a portion of the cathode electrode CE overlapping it configure one light emitting element LD (refer to FIG. 2). In other words, each of the light emitting elements LD of the first to third sub-pixels SP1 to SP3 may include one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and in case that the excitons transit from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE may be disposed on the cathode electrode CE. The encapsulation layer TFE may cover the light emitting element layer LDL and/or the pixel circuit layer PCL. The encapsulation layer TFE may be configured to prevent oxygen, moisture, and/or the like from permeating to the light emitting element layer LDL. In embodiments, the encapsulation layer TFE may include a structure in which one or more inorganic layers and one or more organic layers are alternately stacked on each other. For example, the inorganic layer may include silicon nitride, silicon oxide, silicon oxynitride (SiOxNy), or the like. For example, the organic layer may include an organic insulating material such as acrylic resin (polyacrylates resin), epoxy resin, phenolic resin, polyamides resin, polyimides resin, unsaturated polyesters resin, poly phenylenethers resin, polyphenylenesulfides resin, or benzocyclobutene (BCB). However, materials of the organic layer and the inorganic layer of the encapsulation layer TFE are not limited thereto.

In order to improve an encapsulation efficiency of the encapsulation layer TFE, the encapsulation layer TFE may further include a thin film including aluminum oxide (AlOx). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through an atomic layer deposition (ALD) method. However, embodiments are not limited thereto. The encapsulation layer TFE may further include a thin film formed of at least one of various materials suitable for improving the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL is configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA may be disposed on the color filter layer CFL. The lens array LA may include lenses LS respectively corresponding to the first to third sub- pixels SP1 to SP3. Each of the lenses LS may improve light output efficiency by outputting the light emitted from the light emitting structure EMS to an intended path. The lens array LA may have a relatively high refractive index. For example, the lens array LA may have a refractive index higher than that of the overcoat layer OC. In embodiments, the lenses LS may include an organic material. In embodiments, the lenses LS may include an acrylate material. However, a material of the lenses LS is not limited thereto.

In embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. Specifically, in a central area of the display area DA, a center of the color filter CF and a center of the lens LS may be aligned with or overlap a center of the opening OP of the corresponding pixel definition layer PDL when viewed in the third direction DR3. For example, in the central area of the display area DA, the opening OP of the pixel defining layer PDL may completely overlap the corresponding color filter CF of the color filter layer CFL and the corresponding lens LS of the lens array LA. In an area adjacent to the non-display area NDA in the display area DA, the center of the color filter CF and the center of the lens LS may be shifted from the center of the opening OP of the corresponding pixel defining layer PDL when viewed in the third direction DR3. For example, in the area adjacent to the non-display area NDA in the display area DA, the opening OP of the pixel defining layer PDL may be partially overlapped by the corresponding color filter CF of the color filter layer CFL and the corresponding lens LS of the lens array LA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by a predetermined or selected angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than that of the lens array LA.

The cover window CW may be disposed on the overcoat layer OC. The cover window CW may be configured to protect layers thereunder. The cover window CW may have a refractive index higher than that of the overcoat layer OC. The cover window CW may include glass, but embodiments are not limited thereto. For example, the cover window CW may be an encapsulation glass configured to protect components disposed thereunder. In other embodiments, the cover window CW may be omitted.

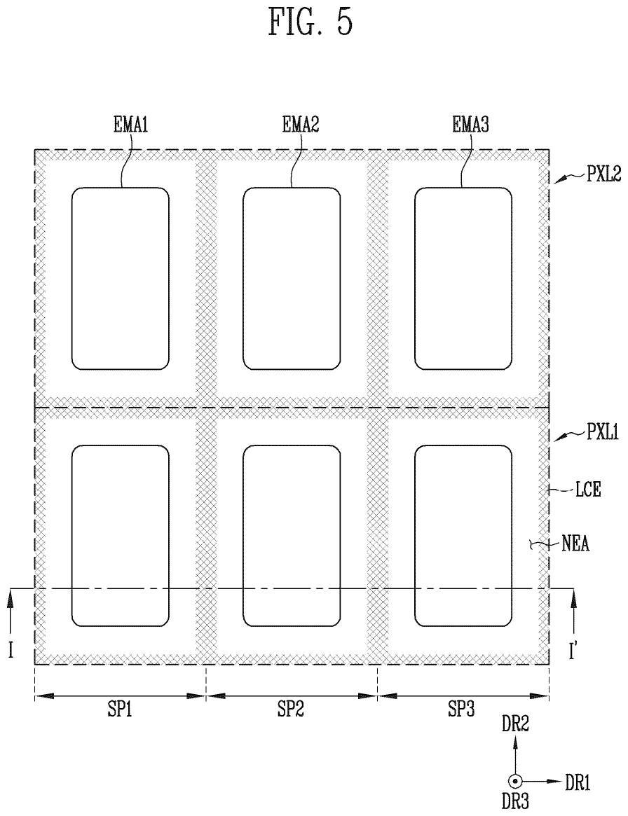

FIG. 5 is a schematic plan view illustrating an embodiment of the pixels of FIG. 4. The remaining pixels may be configured similarly to the first and second pixels PXL1 and PXL2.

Referring to FIGS. 4 and 5, each of the first and second pixels PXL1 and PXL2 may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the light emitting structure EMS (refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described with reference to FIG. 5, each emission area may be understood as the opening OP of the pixel defining layer PDL corresponding to each of the first to third sub-pixels SP1 to SP3.

A leakage electrode LCE may be disposed in a boundary area between the first to third sub-pixels SP1 to SP3. The leakage electrode LCE may be disposed not only in a boundary area between sub-pixels (for example, the sub-pixels SP1 to SP3) adjacent to each other but also in a boundary area between pixels (for example, the pixels PXL1 and PXL2) adjacent to each other.

A detailed description of the leakage electrode LCE is described later.

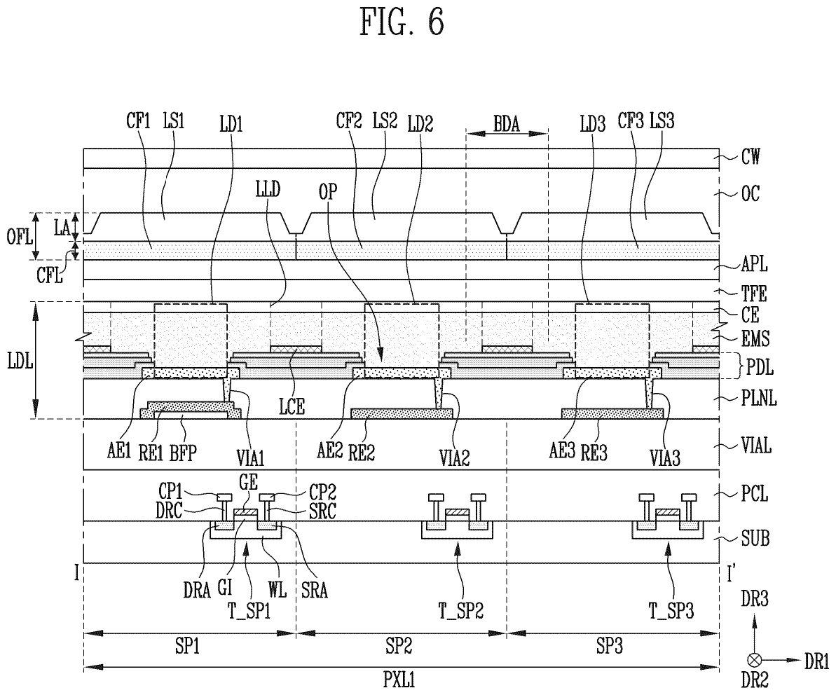

FIG. 6 is a schematic cross-sectional view taken along line I-I′ of FIG. 5.

Referring to FIG. 6, the substrate SUB and the pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1, the transistor T_SP2 of the second sub-pixel SP2 may be any one of the transistors included in the sub-pixel circuit SPC of the second sub-pixel SP2, and the transistor T_SP3 of the third sub-pixel SP3 may be any one of the transistors included in the sub-pixel circuit SPC of the third sub-pixel SP3. In FIG. 6, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be disposed in the substrate SUB. A well WL formed through an ion injection process may be disposed in the substrate SUB, and the source area SRA and the drain area DRA may be spaced apart from each other in the well WL. An area between the source area SRA and the drain area DRA in the well WL may be defined as a channel area.

The gate electrode GE may overlap the channel area between the source area SRA and the drain area DRA and may be disposed in the pixel circuit layer PCL. The gate electrode GE may be spaced apart from the well WL or the channel area by an insulating material such as a gate insulating layer GI. The gate electrode GE may include a conductive material.

Multiple layers included in the pixel circuit layer PCL may include insulating layers and conductive patterns disposed between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL may be disposed on the pixel circuit layer PCL. The via layer VIAL may cover the pixel circuit layer PCL and may have an overall flat surface. The via layer VIAL may be configured to planarize steps on the pixel circuit layer PCL. The via layer VIAL may include at least one of silicon oxide (SiOx), silicon nitride (SiNx), and silicon carbon nitride (SiCN), but embodiments are not limited thereto.

The light emitting element layer LDL may be disposed on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 may be disposed in the first to third sub-pixels SP1 to SP3, respectively. Each of the first to third reflective electrodes RE1 to RE3 may contact the circuit element disposed in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them, but embodiments are not limited thereto.

In embodiments, a connection electrode may be disposed under each of the first to third reflective electrodes RE1 to RE3. The connection electrode may improve an electrical connection characteristic between a corresponding reflective electrode and the circuit element of the pixel circuit layer PCL. The connection electrode may have a multilayer structure. The multilayer structure may include titanium (Ti), titanium nitride (TiN), tantalum nitride (TaN), or the like, but embodiments are not limited thereto. In embodiments, a corresponding reflective electrode may be positioned between multiple layers of the connection electrode.

A buffer pattern BFP may be disposed under at least one of the first to third reflective electrodes RE1 to RE3. The buffer pattern BFP may include an inorganic material such as silicon carbon nitride, but embodiments are not limited thereto. By disposing the buffer pattern BFP, a height of the third direction DR3 of a corresponding reflective electrode may be adjusted. For example, the buffer pattern BFP may be disposed between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. The light emitted from the light emitting layer of the light emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light emitting layer of the corresponding light emitting structure EMS.

The first sub-pixel SP1 may have a resonance distance shorter than that of another sub-pixel by the buffer pattern BFP. The resonance distance adjusted as described above may allow light of a specific wavelength range (for example, red color light) to be effectively and efficiently amplified. Accordingly, the first sub-pixel SP1 may effectively and efficiently output light of a corresponding wavelength range.

In FIG. 6, the buffer pattern BFP may be provided to the first sub-pixel SP1 and may not be provided to the second and third sub-pixels SP2 and SP3, but embodiments are not limited thereto. The buffer pattern may also be provided to at least one of the second and third sub-pixels SP2 and SP3 to adjust the resonance distance of at least one of the second and third sub-pixels SP2 and SP3. For example, the buffer pattern BFP may also be provided to the second sub-pixel SP2, and the resonance distance of the second sub-pixel SP2 may be adjusted. For example, the first to third sub-pixels SP1 to SP3 may correspond to red, green, and blue, respectively, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize steps between the first to third reflective electrodes RE1 to RE3, a planarization layer PLNL may be disposed on the via layer VIAL and the first to third reflective electrodes RE1 to RE3. The planarization layer PLNL may generally cover the first to third reflective electrodes RE1 to RE3 and the via layer VIAL, and may have a flat surface. In embodiments, the planarization layer PLNL may be omitted.

On the planarization layer PLNL, the first to third anode electrodes AE1 to AE3 respectively overlapping the first to third reflective electrodes RE1 to RE3 may be disposed. The first to third anode electrodes AE1 to AE3 may respectively have shapes similar to those of the first to third emission areas EMA1 to EMA3 of FIG. 6 when viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

In embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). However, a material of the first to third anode electrodes AE1 to AE3 is not limited thereto. For example, the first to third anode electrodes AE1 to AE3 may include titanium nitride.

In embodiments, insulating layers for adjusting a height of one or more of the first to third anode electrodes AE1 to AE3 may be further provided. The insulating layers may be disposed between one or more of the first to third anode electrodes AE1 to AE3 and corresponding reflective electrodes. The planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL may be disposed on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define the emission area of each of the first to third sub-pixels SP1 to SP3. As described above, the pixel defining layer PDL may be disposed in the non-emission area NEA of FIG. 5 and may define the first to third emission areas EMA1 to EMA3 of FIG. 5.

In embodiments, the pixel defining layer PDL may include inorganic insulating layers. Each of the inorganic insulating layers may include at least one of silicon oxide (SiOx) and silicon nitride (SiNx). For example, the pixel defining layer PDL may include first to third inorganic insulating layers stacked on each other, and each of the first to third inorganic insulating layers may include silicon nitride, silicon oxide, and silicon oxynitride (SiOxNy). However, embodiments are not limited thereto. The first to third inorganic insulating layers may have a step-shaped cross section in an area adjacent to the opening OP.

The leakage electrode LCE may be disposed in the boundary area BDA between the sub-pixels adjacent to each other. In other words, the leakage electrode LCE may be disposed in each of boundary areas between the sub-pixels SP of FIG. 3.

The leakage electrode LCE may form a current path through which a leakage current flowing to the adjacent sub-pixels (for example, the sub-pixels SP1 to SP3) along the light emitting structure EMS may flow in the boundary area BDA. A detailed description of this aspect is described later.

The light emitting structure EMS may be disposed on the anode electrodes AE1 to AE3 exposed by the opening OP of the pixel defining layer PDL. The light emitting structure EMS may be disposed on the leakage electrodes LCE disposed on the pixel defining layer PDL. The light emitting structure EMS may fill the opening OP of the pixel defining layer PDL and may be disposed entirely across the first to third sub-pixels SP1 to SP3.

The cathode electrode CE may be disposed on the light emitting structure EMS. The cathode electrode CE may be commonly provided to the first to third sub-pixels SP1 to SP3. The cathode electrode CE may be commonly provided to the leakage electrode LCE. The cathode electrode CE may function as a half mirror that partially transmits and partially reflects the light emitted from the light emitting structure EMS.

The first anode electrode AE1, a portion of the light emitting structure EMS overlapping the first anode electrode AE1, and a portion of the cathode electrode CE overlapping the first anode electrode AE1 may configure the first light emitting element LD1. The second anode electrode AE2, a portion of the light emitting structure EMS overlapping the second anode electrode AE2, and a portion of the cathode electrode CE overlapping the second anode electrode AE2 may configure the second light emitting element LD2. The third anode electrode AE3, a portion of the light emitting structure EMS overlapping the third anode electrode AE3, and a portion of the cathode electrode CE overlapping the third anode electrode AE3 may configure the third light emitting element LD3.

The leakage electrode LCE, a portion of the light emitting structure EMS overlapping the leakage electrode LCE, and a portion of the cathode electrode CE overlapping the leakage electrode LCE may configure a leakage element LLD.

The encapsulation layer TFE may be disposed on the cathode electrode CE. The encapsulation layer TFE may prevent oxygen, moisture, and/or the like from permeating to the light emitting element layer LDL.

The optical functional layer OFL may be disposed on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

In embodiments, the first to third color filters CF1 to CF3 may partially overlap in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first to third sub-pixels SP1 to SP3. Each of the first to third lenses LS1 to LS3 may improve light output efficiency by outputting light emitted from the first to third light emitting elements LD1 to LD3 to an intended path.

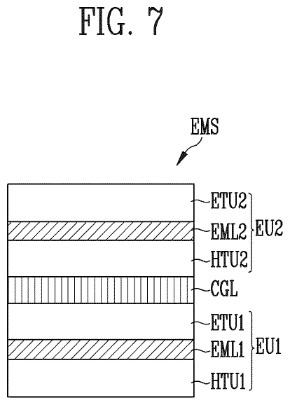

FIG. 7 is a schematic cross-sectional view illustrating an embodiment of a light emitting structure included in any one of the first to third light emitting elements of FIG. 6.

Referring to FIG. 7, the light emitting structure EMS may have a tandem structure in which first and second light emitting units EU1 and EU2 are stacked on each other. The light emitting structure EMS may be configured substantially equally in each of the first to third light emitting elements LD1 to LD3 and the leakage element LLD.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer, and may further include a hole buffer layer, an electron blocking layer, and the like if necessary. The first and second hole transport units HTU1 and HTU2 may have configurations equal to each other or different from each other.

Each of the first and second electron transport units ETU1 and ETU2 may include at least one of an electron injection layer and an electron transport layer, and may further include an electron buffer layer, a hole blocking layer, and the like. The first and second electron transport units ETU1 and ETU2 may have configurations equal to each other or different from each other.

A connection layer, which may be provided in a form of a charge generation layer CGL, may be disposed between the first light emitting unit EU1 and the second light emitting unit EU2 to connect the first light emitting unit EU1 and the second light emitting unit EU2 to each other. In embodiments, the charge generation layer CGL may have a stack structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide metal, or a combination thereof. However, embodiments are not limited thereto.

In embodiments, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate light of a blue color, and the second light emitting layer EML2 may generate light of a yellow color. In embodiments, the second light emitting layer EML2 may include a structure in which a first sub light emitting layer configured to generate light of a red color and a second sub light emitting layer configured to generate light of a green color are stacked on each other. The light of the red color and the light of the green color may be mixed, and thus the light of the yellow color may be provided. An intermediate layer configured to perform a function of transporting holes and/or blocking transport of electrons may be further disposed between the first and second sub light emitting layers.

In other embodiments, the first light emitting layer EML1 and the second light emitting layer EML2 may generate light of the same color.

The light emitting structure EMS may be formed through a method of vacuum deposition, inkjet printing, or the like, but embodiments are not limited thereto.

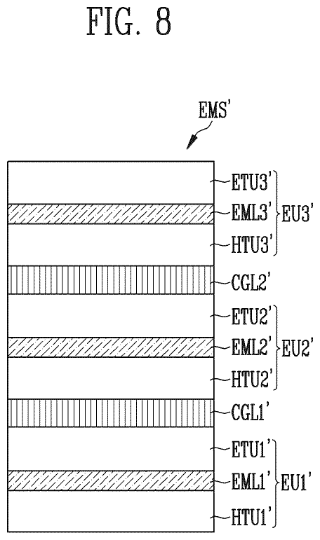

FIG. 8 is a schematic cross-sectional view illustrating another embodiment of a light emitting structure included in any one of the first to third light emitting elements of FIG. 6.

Referring to FIG. 8, the light emitting structure EMS′ may have a tandem structure in which first to third light emitting units EU1′ to EU3′ are stacked on each other. The light emitting structure EMS′ may be configured substantially equally in each of the first to third light emitting elements LD1 to LD3 and the leakage element LLD of FIG. 6.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and may further include a hole buffer layer, an electron blocking layer, and the like. The first to third hole transport units HTU1′ to HTU3′ may have configurations equal to each other or different from each other.

Each of the first to third electron transport units ETU1′ to ETU3′ may include at least one of an electron injection layer and an electron transport layer, and may further include an electron buffer layer, a hole blocking layer, and the like. The first to third electron transport units ETU1′ to ETU3′ may have configurations equal to each other or different from each other.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In embodiments, the first to third light emitting layers EML1′ to EML3′ may generate light of different colors. Light emitted from each of the first to third light emitting layers EML1′ to EML3′ may be mixed and may be viewed as white light. For example, the first emitting layer EML1′ may generate light of a blue color, the second emitting layer EML2′ may generate light of a green color, and the third emitting layer EML3′ may generate light of a red color.

In other embodiments, two or more of the first to third light emitting layers EML1′ to EML3′ may generate light of the same color.

Differently from that shown in FIGS. 7 and 8, the light emitting structure EMS of FIG. 6 may include one light emitting unit in each of the first to third light emitting elements LD1 to LD3 and the leakage element LLD. The light emitting unit included in each of the first to third light emitting elements LD1 to LD3 may be configured to emit light of different colors. For example, the light emitting unit of the first light emitting element LD1 may emit the light of the red color, the light emitting unit of the second light emitting element LD2 may emit the light of the green light, and the light emitting unit of the third light emitting element LD3 may emit the light of the blue color. Different from that shown in FIG. 6, the light emitting units of the first to third sub-pixels SP1 to SP3 may be separated from each other, and each of them may be disposed in the opening OP of the pixel defining layer PDL. At least a portion of the color filters CF1 to CF3 may be omitted.

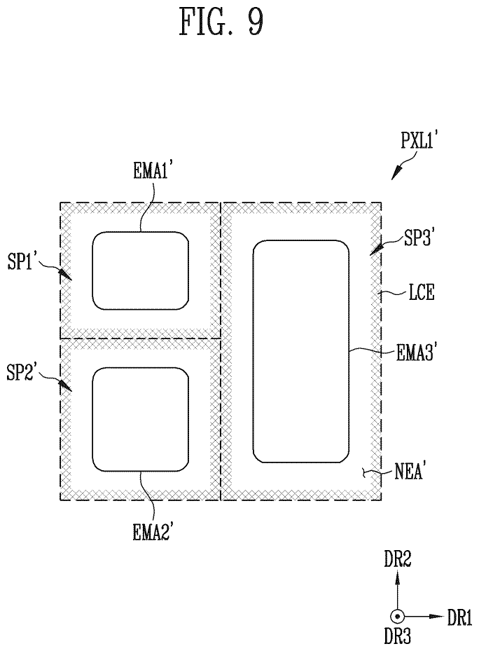

FIG. 9 is a schematic plan view illustrating another embodiment of any one of the pixels of FIG. 4.

Referring to FIG. 9, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA' around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area greater than that of the first sub-pixel SP1′, and the third sub-pixel SP3′ may have an area greater than that of the second sub-pixel SP2′. Accordingly, the second emission area EMA2′ may have an area greater than the first emission area EMA1′, and the third emission area EMA3′ may have an area greater than that of the second emission area EMA2′. However, embodiments are not limited thereto. For example, the first and second sub-pixels SP1′ and SP2′ may have substantially the same area, and the third sub-pixel SP3′ may have an area greater than that of each of the first and second sub-pixels SP1′ and SP2′. As described above, the areas of the first to third sub-pixels SP1′ to SP3′ may vary according to embodiments.

Similarly, the leakage electrode LCE may be disposed in a boundary area between the first to third sub-pixels SP1′ to SP3′. The leakage electrode LCE may be disposed not only in a boundary area between the sub-pixels (for example, the sub-pixels SP1′ to SP3′) but also in a boundary area between the pixels adjacent to each other.

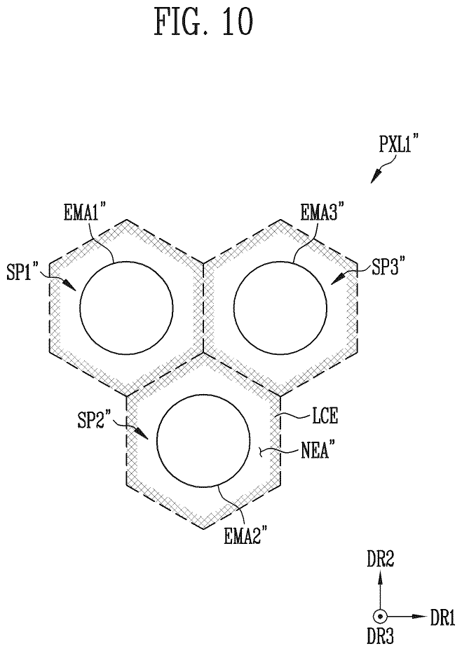

FIG. 10 is a schematic plan view illustrating still another embodiment of any one of the pixels of FIG. 4.

Referring to FIG. 10, a first pixel PXL1″ may include first to third sub-pixels SP1″ to SP3″. The first sub-pixel SP1″ may include a first emission area EMA1″ and a non-emission area NEA″ around the first emission area EMA1″. The second sub-pixel SP2″ may include a second emission area EMA2″ and a non-emission area NEA″ around the second emission area EMA2″. The third sub-pixel SP3″ may include a third emission area EMA3″ and a non-emission area NEA″ around the third emission area EMA3″.

The first to third sub-pixels SP1″ to SP3″ may have polygonal shapes when viewed in the third direction DR3. For example, shapes of the first to third sub-pixels SP1″ to SP3″ may be hexagonal shapes as shown in FIG. 2.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be disposed in a direction inclined by an acute angle based on the second direction DR2 (or a diagonal direction) with respect to the first sub-pixel SP1″.

Similarly, the leakage electrode LCE may be disposed in a boundary area between the first to third sub-pixels SP1″ to SP3″. The leakage electrode LCE may be disposed not only in a boundary area between the sub-pixels (for example, the sub-pixels SP1″ to SP3″) but also in a boundary area between the pixels adjacent to each other.

An arrangement of the sub-pixels shown in FIGS. 5, 9, and 10 is only an example, and embodiments are not limited thereto. Each pixel may include two or more sub-pixels SP, the sub-pixels SP may be arranged in various methods, the respective sub-pixels SP may have various shapes, and respective emission areas EMA1, EMA2, and EMA3 thereof may also have various shapes.

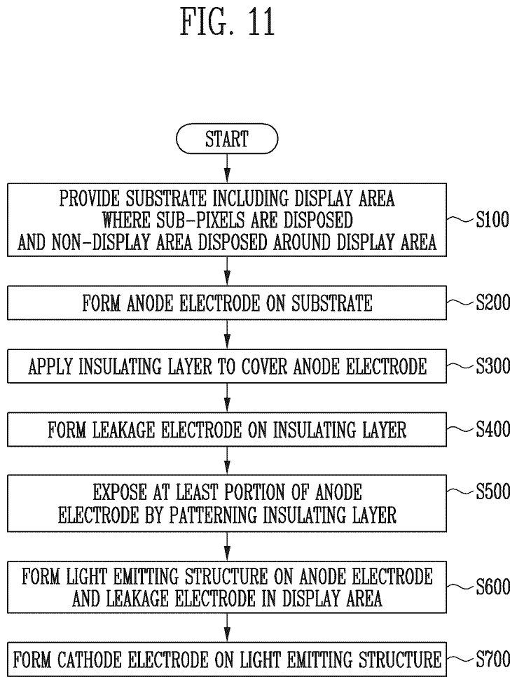

FIG. 11 is a flowchart illustrating a method of manufacturing a display device according to embodiments of the disclosure.

Referring to FIG. 11, the method of manufacturing the display device may include providing a substrate including a display area on which sub-pixels are disposed and a non-display area disposed around the display area (S100), forming an anode electrode on the substrate (S200), applying an insulating layer (for example, a pixel defining layer) to cover the anode electrode (S300), forming a leakage electrode on the insulating layer (S400), exposing at least a portion of the anode electrode by patterning the insulating layer (S500), forming a light emitting structure on the anode electrode and the leakage electrode in the display area (S500), and forming a cathode electrode on the light emitting structure (S600).

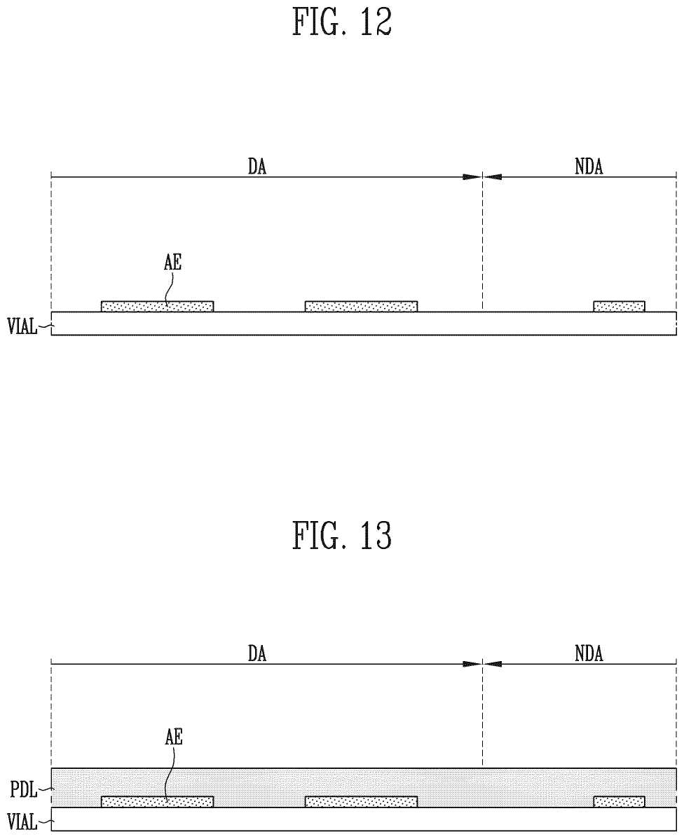

Hereinafter, the disclosure is described in detail with reference to FIGS. 12 to 17.

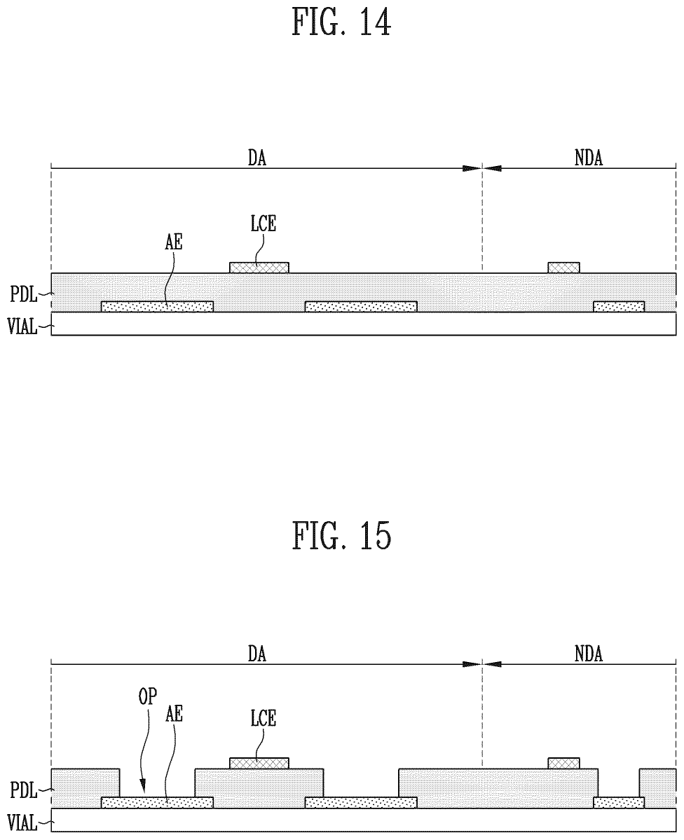

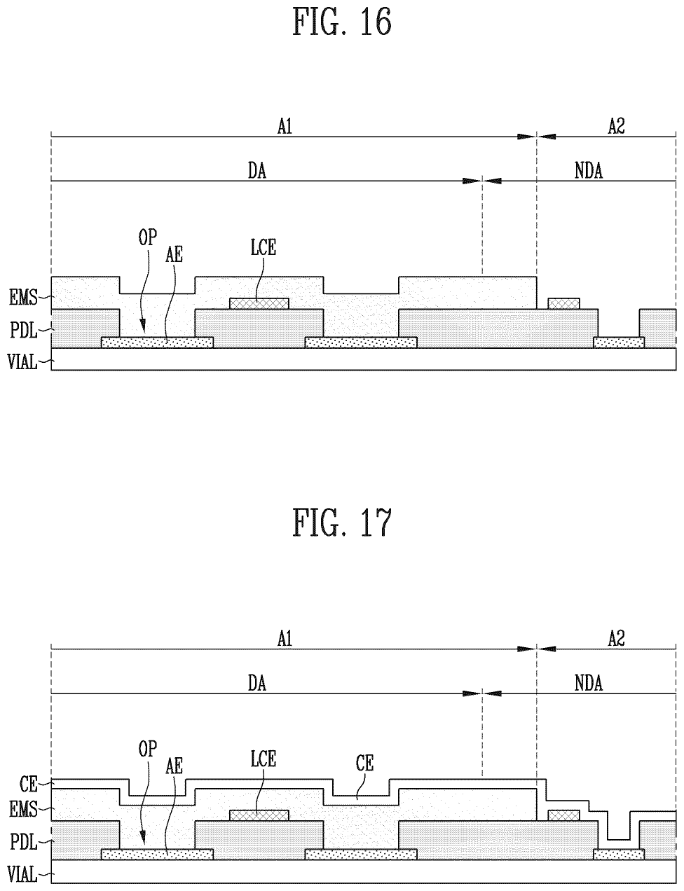

FIG. 12 is a schematic diagram illustrating step S200 of FIG. 11, FIG. 13 is a schematic diagram illustrating step S300 of FIG. 11, FIG. 14 is a schematic diagram illustrating step S400 of FIG. 11, FIG. 15 is a schematic diagram illustrating step S500 of FIG. 11, FIG. 16 is a schematic diagram illustrating step S600 of FIG. 11, and FIG. 17 is a schematic diagram illustrating step S700 of FIG. 11.

FIGS. 13 to 17 only illustrate the pixel defining layer PDL as a single layer for convenience of description, and the disclosure is not limited thereto.

Referring to FIG. 12, the anode electrode AE may be formed on the via layer VIAL. The anode electrode AE may be applied on the via layer VIAL and patterned to configure the light emitting element LD (refer to FIG. 2) in the display area DA.

The anode electrode AE formed in the non-display area NDA may be connected to the cathode electrode CE (refer to FIG. 17 described later) and may transmit the second power voltage VSS (refer to FIG. 2) to the cathode electrode CE (refer to FIG. 17 described later).

In an embodiment, the anode electrode AE disposed in the non-display area NDA is illustrated as being shorter than the anode electrode AE disposed in the display area DA, however, in the disclosure, the disclosure is not limited to a length of the anode electrode AE in the non-display area NDA.

Referring to FIG. 13, the pixel defining layer PDL may be applied to cover the anode electrode AE. For example, the pixel defining layer PDL may be applied to cover the anode electrode AE and the via layer VIAL.

Referring to FIG. 14, the leakage electrode LCE may be formed on the pixel defining layer PDL. The leakage electrode LCE may be applied on the pixel defining layer PDL, may be patterned, and may be disposed between the anode electrodes AE.

In an embodiment, the leakage electrode LCE disposed in the non-display area NDA is illustrated as being shorter than the leakage electrode LCE disposed in the display area DA, however, in the disclosure, the disclosure is not limited to a length of the leakage electrode LCE in the non-display area NDA.

Referring to FIG. 15, the pixel defining layer PDL may be patterned to expose at least a portion of the anode electrode AE. For example, the pixel defining layer PDL may include the opening OP exposing a portion of each of the anode electrodes AE, and the opening OP may correspond to the emission areas EMA1 to EMA3 (refer to FIG. 5).

In FIG. 15, the pixel defining layer PDL is illustrated as exposing a portion of each anode electrode AE, but the disclosure is not limited thereto. For example, the pixel defining layer PDL may expose an entirety of each of the anode electrodes AE, and a portion where the pixel defining layer PDL and the anode electrodes AE overlap may not exist.

The leakage electrode LCE may be shorter than a distance between the openings OP. In case that the pixel defining layer PDL exposes the entirety of each of the anode electrodes AE, the leakage electrode LCE may be shorter than a distance between the anode electrodes AE.

In case that the leakage electrode LCE is applied after the pixel defining layer PDL is patterned, the anode electrode AE may be damaged in a process of patterning the leakage electrode LCE (that is, a process of removing the leakage electrode LCE in the emission areas EMA1 to EMA3 (refer to FIG. 5). Therefore, in order to prevent the damage, the pixel defining layer PDL may be patterned after the leakage electrode LCE is formed.

Referring to FIG. 16, the light emitting structure EMS may be formed in a first area A1. The first area A1 may include the display area DA. That is, the light emitting structure EMS may be disposed on the anode electrode AE and the leakage electrode LCE in the display area DA.

The light emitting structure EMS may fill the opening OP of the pixel defining layer PDL, and may be formed entirely on the pixel defining layer PDL. Accordingly, a leakage current may flow through the charge generation layer CGL between the sub-pixels adjacent to each other. However, as the leakage electrode LCE is disposed, the leakage current between the sub-pixels adjacent to each other may be reduced. A detailed description of this aspect is described later.

In an embodiment, it is illustrated that the first area A1 and the display area DA are different, but the disclosure is not limited thereto. For example, the first area A1 and the display area DA may coincide.

Referring to FIG. 17, the cathode electrode CE may be formed on the light emitting structure EMS in the display area DA. The cathode electrode CE may be formed entirely on the light emitting structure EMS in the first area A1 including the display area DA.

The cathode electrode CE may be formed on the pixel defining layer PDL in a second area A2 where the light emitting structure EMS is not formed. For example, the cathode electrode CE may be formed entirely on the pixel defining layer PDL in the second area A2 including a portion of the non-display area NDA.

The cathode electrode CE may be formed on the leakage electrode LCE in at least a portion of the non-display area NDA (for example, the second area A2). For example, the cathode electrode CE may contact the leakage electrode LCE in at least a portion of the non-display area NDA (for example, the second area A2).

Accordingly, the same voltage (for example, the second power voltage VSS (refer to FIG. 1)) as that of the cathode electrode CE may be applied to the leakage electrode LCE. As shown in FIG. 5, the leakage electrode LCE may be integrally formed in a mesh shape over the entire display area DA and non-display area NDA. Therefore, the same voltage as that of the cathode electrode CE may be applied to the entire leakage electrode LCE.

The cathode electrode CE may be connected to the anode electrode AE in at least a portion of the non-display area NDA (for example, the second area A2). The cathode electrode CE may receive the second power voltage VSS (refer to FIG. 1) through the anode electrode AE in the non-display area NDA. The anode electrode AE may receive the second power voltage VSS (refer to FIG. 1) through a conductive pattern disposed under the anode electrode AE.

As described above, as the cathode electrode CE is connected to the anode electrode AE in the second area A2 where the light emitting structure EMS is not formed, the number of contact holes and masks used in a process may be reduced.

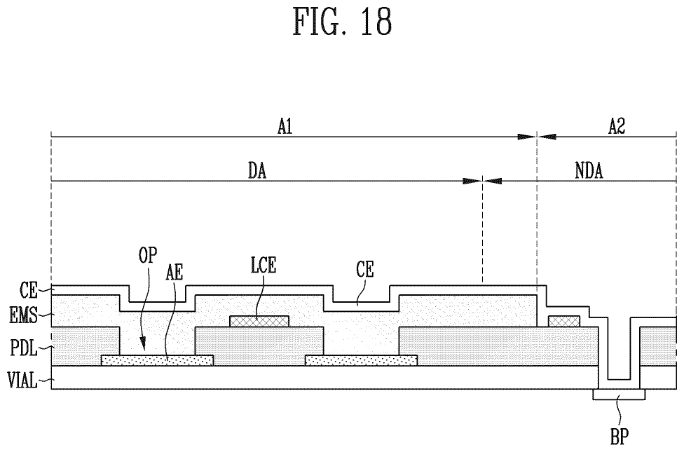

FIG. 18 is a schematic cross-sectional view of a portion of a display device according to embodiments of the disclosure.

For convenience of description, FIG. 18 illustrates only some configurations, and remaining configurations are omitted. For convenience of description, FIG. 18 illustrates that a conductive pattern BP may be disposed directly under the via layer VIAL. However, the conductive pattern BP does not necessarily have to be disposed directly under the via layer VIAL, and a pattern disposed under the via layer VIAL is sufficient as the conductive pattern BP.

Since the display device according to an embodiment may be substantially the same as a configuration of the display device of FIG. 1 except that the cathode electrode CE is connected to the conductive pattern BP disposed under the anode electrode AE in the second area A2, the same reference numbers and symbols are used for equal or similar components, and a redundant description is omitted.

Referring to FIG. 18, the cathode electrode CE may be connected to the conductive pattern BP disposed under the anode electrode AE in at least a portion of the non-display area NDA (for example, the second area A2). For example, the conductive pattern BP may be a conductive pattern of the same layer as the first and second conductive patterns CP1 and CP2 (refer to FIG. 6). For example, the second power voltage VSS (refer to FIG. 1) may be applied to the conductive pattern BP and may be provided to the cathode electrode CE through the conductive pattern BP.

The disclosure is not limited to a type of the conductive pattern disposed under the anode electrode AE, and a conductive material disposed under the anode electrode AE is sufficient as the conductive pattern.

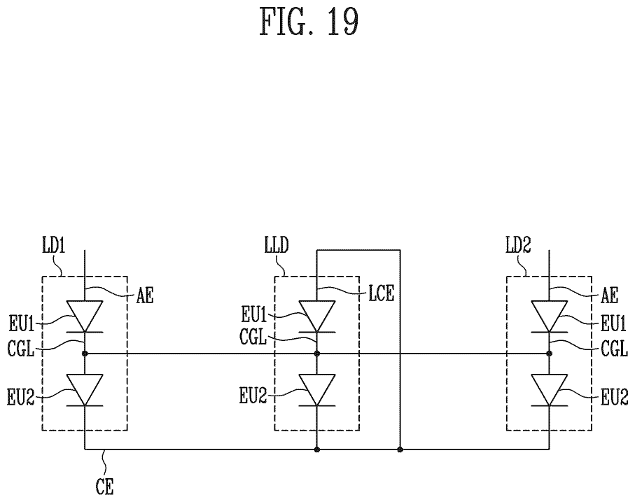

FIG. 19 is a schematic diagram of a circuit illustrating the first and second light emitting elements and the leakage element of FIG. 6.

In FIG. 19, a circuit corresponding to two light emitting elements LD1 and LD2 among the light emitting elements LD1 to LD3 of FIG. 6 are shown for clarity and concise description. A circuit corresponding to remaining light emitting elements may be configured similarly.

For convenience of description, FIG. 19 assumes that the first and second light emitting elements LD1 and LD2 and the leakage element LLD have a structure of FIG. 7.

Referring to FIG. 19, the first light emitting unit EU1 of the light emitting elements LD1 and LD2 may be connected to the anode electrode AE and the charge generation layer CGL. The second light emitting unit EU2 of the first and second light emitting elements LD1 and LD2 may be connected to the charge generation layer CGL and the cathode electrode CE.

The charge generation layer CGL and the cathode electrode CE may be shared by the light emitting elements LD1 and LD2 and the leakage element LLD. Therefore, the first light emitting unit EU1 of the leakage element LLD may also be connected to the charge generation layer CGL, and the second light emitting unit EU2 of the leakage element LLD may also be connected to the charge generation layer CGL and the cathode electrode CE.

The first light emitting unit EU1 of the leakage element LLD may be connected to the leakage electrode LCE. As described above, the leakage electrode LCE may be connected to the cathode electrode CE.

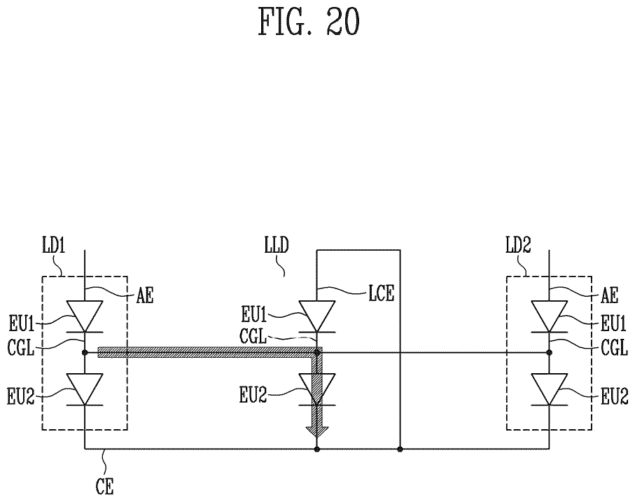

FIG. 20 is a schematic diagram of a circuit illustrating the leakage current.

Referring to FIG. 20, as described above, the charge generation layer CGL and the cathode electrode CE may be shared by the light emitting elements LD1 and LD2 and the leakage element LLD. Accordingly, in case that the first light emitting element LD1 emits light and the second light emitting element LD2 does not emit light, the leakage current may flow along the charge generation layer CGL of the first light emitting element LD1.

At least a portion of the leakage current may flow to the second light emitting unit EU2 of the leakage element LLD. Ideally, a resistance of the charge generation layer CGL between the light emitting elements LD1 and LD2 does not exist, but in reality, a resistance exists, the leakage current flowing to the second light emitting element LD2 may be greater than the leakage current flowing to the leakage element LLD. Accordingly, the leakage current flowing to the second light emitting element LD2 may be reduced.

A voltage applied to the leakage electrode LCE (for example, the second power voltage VSS (refer to FIG. 1) may be less than a voltage of the anode electrode AE at the lowest grayscale. Accordingly, a current may not flow through the first light emitting unit EU1 connected to the leakage electrode LCE, and the first light emitting unit EU1 may function as a capacitor. As the first light emitting unit EU1 functions as the capacitor, even though a leakage current occurs, a voltage of the charge generation layer CGL connected to the leakage electrode LCE may slowly increase.

In case that any one of the sub-pixels adjacent to each other emits light, the one may affect another one due to coupling. That is, noise may occur in the other one. As the leakage electrode LCE is formed in the boundary area between the sub-pixels (that is, the light emitting elements LD1 and LD2), and a constant voltage (for example, the second power voltage VSS (refer to FIG. 1) is applied to the leakage electrode, noise due to coupling between the sub-pixels adjacent may be reduced.

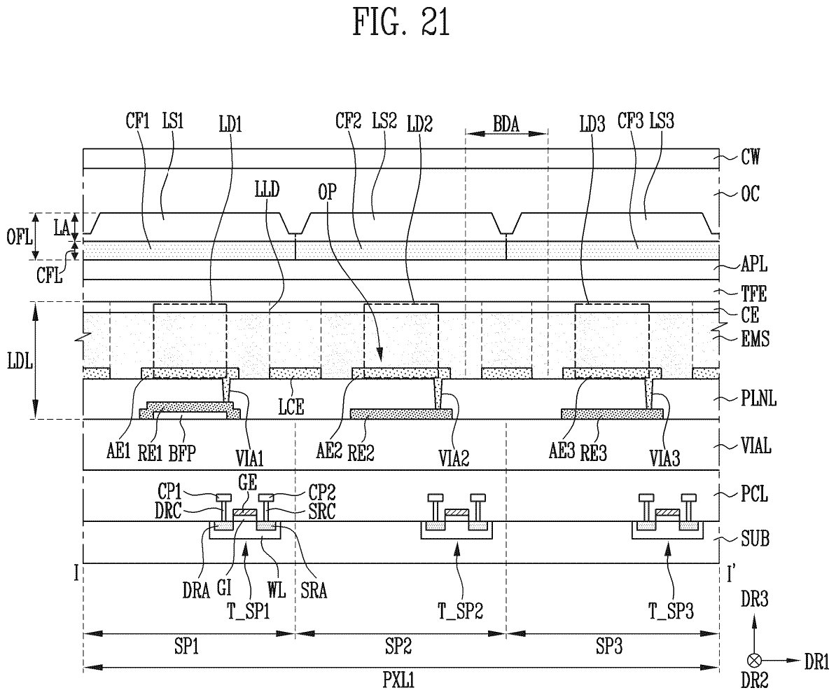

FIG. 21 is a schematic cross-sectional view of a display device according to embodiments of the disclosure. FIG. 21 is another example of the cross-sectional view taken along the line I-I′ of FIG. 5.

Since the display device according to an embodiment may be substantially the same as a configuration of the display device of FIG. 6 except that the pixel defining layer PDL is omitted, the same reference numerals and reference symbols are used for equal or similar components, and a redundant description is omitted.

Referring to FIG. 21, the leakage electrode LCE may be formed on a planarization layer PLNL. For example, the leakage electrode LCE may be formed on the same layer as the first to third anode electrodes AE1, AE2, and AE3. For example, the leakage electrode LCE may be formed through the same process as the first to third anode electrodes AE1, AE2, and AE3. However, the leakage electrode LCE does not necessarily have to be formed through the same process.

The leakage electrode LCE may be disposed between the anode electrodes AE1 to AE3. A length of the leakage electrode LCE may be shorter than a distance between the anode electrodes AE1 to AE3.

The light emitting structure EMS may be disposed on the anode electrodes AE1 to AE3 and the leakage electrodes LCE. For example, the light emitting structure EMS may be disposed entirely on the planarization layer PLNL, the anode electrodes AE1 to AE3, and the leakage electrodes LCE.

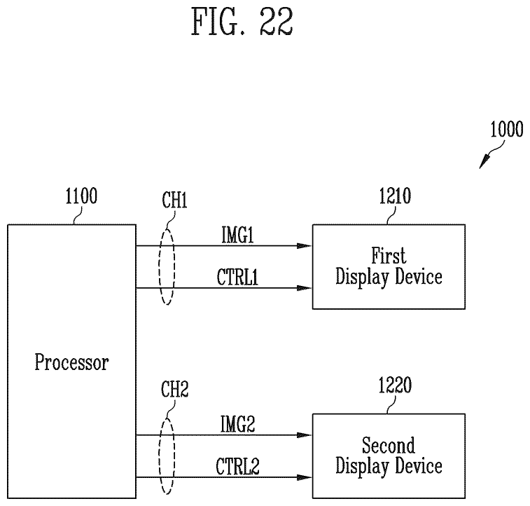

FIG. 22 is a schematic block diagram illustrating an embodiment of a display system.

Referring to FIG. 22, the display system 1000 may include a processor 1100 and one or more display devices 1210 and 1220. Similarly, the display system 1000 may reduce a leakage current flowing between sub-pixels adjacent to each other through a leakage electrode.

The processor 1100 may perform various tasks and calculations. In embodiments, the processor 1100 may include an application processor, a graphic processor, a microprocessor, a central processing unit (CPU), and the like. The processor 1100 may be connected to other components of the display system 1000 through a bus system and may control other components.

In FIG. 22, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. The first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. The second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

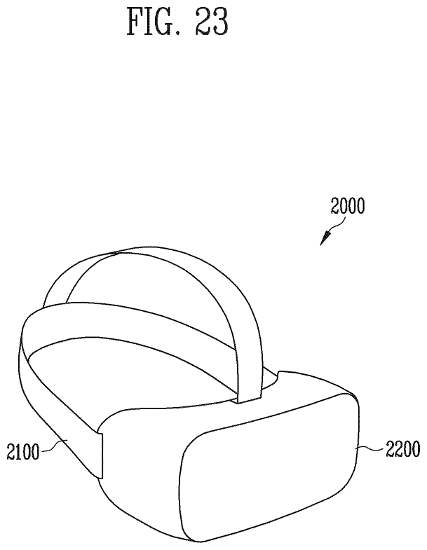

FIG. 23 is a schematic perspective view illustrating an application example of the display system of FIG. 22.

Referring to FIG. 23, the display system 1000 of FIG. 22 may be applied to a head mounted display device 2000. The head mounted display device 2000 may be a wearable electronic device that may be worn on a user's head.

The head mounted display device 2000 may include a head mount band 2100 and a display device accommodation case 2200. The head mount band 2100 may be connected to the display device accommodation case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device accommodation case 2200 may accommodate the first and second display devices 1210 and 1220 of FIG. 22. The display device accommodation case 2200 may further accommodate the processor 1100 of FIG. 22.

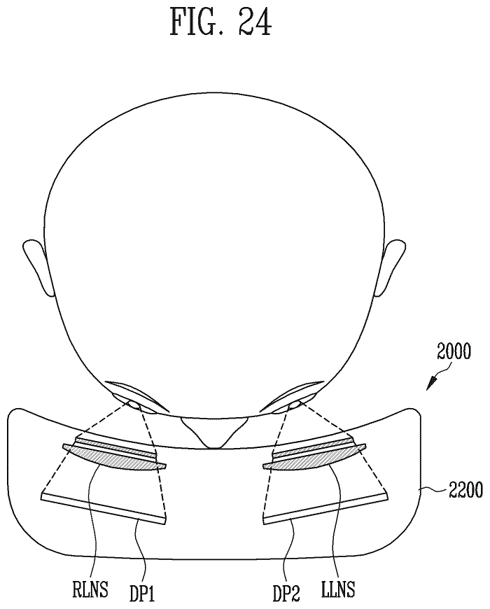

FIG. 24 is a schematic diagram illustrating the head mounted display device worn by a user.

Referring to FIG. 24, in a head mounted display device 2000, a first display panel DP1 of the first display device 1210 and a second display panel DP2 of the second display device 1220 may be disposed. The head mounted display device 2000 may further include one or more lenses LLNS and RLNS.

In the display device accommodation case 2200, the right eye lens RLNS may be disposed between the first display panel DP1 and a user's right eye. In the display device accommodation case 2200, the left eye lens LLNS may be disposed between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. Each display panel may output images respectively corresponding to the sub-areas of the multi-channel lens, and the output images may pass through the respective corresponding sub-areas and may be viewed by the user.

Although specific embodiments and application examples are described herein, other embodiments and modifications may be derived from the above description. Therefore, the spirit of the disclosure is not limited to such embodiments, and extends to include various obvious modifications, and equivalents.

The disclosure may be applied to a display device and an electronic device including the display device. For example, the disclosure may be applied to a digital TV, a 3D TV, a mobile phone, a smart phone, a tablet computer, a VR device, a PC, a home electronic device, a notebook computer, a PDA, a PMP, a digital camera, a music player, a portable game console, a navigation system, and the like.

Although described with reference to the above embodiments, it will be understood that those skilled in the art can variously modify and change the disclosure without departing from the spirit and scope of the disclosure.

What is claimed is:

1. A display device, comprising:
a substrate including:
a display area including sub-pixels; and
a non-display area adjacent to the display area;
a first electrode disposed on the substrate;
a second electrode disposed on the substrate;
a light emitting structure disposed on the first electrode and the second electrode in the display area; and
a third electrode disposed on the light emitting structure in the display area and disposed on the second electrode in at least a portion of the non-display area.

2. The display device according to claim 1, wherein the third electrode electrically contacts the second electrode in the at least the portion of the non-display area.

3. The display device according to claim 1, wherein the third electrode is electrically connected to the first electrode in the at least the portion of the non-display area.

4. The display device according to claim 1, wherein the third electrode is electrically connected to a conductive pattern disposed under the first electrode in the at least the portion of the non-display area.

5. The display device according to claim 1, further comprising:
an insulating layer disposed on the first electrode and including an opening exposing at least a portion of the first electrode,
wherein the second electrode is disposed on the insulating layer.

6. The display device according to claim 5, wherein the third electrode extends to the insulating layer in the at least the portion of the non-display area.

7. The display device according to claim 5, wherein
the light emitting structure fills the opening, and
the light emitting structure is entirely disposed on the insulating layer in the display area.

8. The display device according to claim 1, wherein the light emitting structure comprises:
a first light emitting unit;
a second light emitting unit disposed on the first light emitting unit; and
a connection layer disposed between the first light emitting unit and the second light emitting unit and electrically connecting the first light emitting unit and the second light emitting unit.

9. The display device according to claim 1, wherein a voltage applied to the second electrode is less than a voltage of the first electrode at a lowest grayscale.

10. The display device according to claim 1, wherein
the second electrode is disposed in a boundary area between at least two of the sub-pixels, and
the at least two of the sub-pixels are adjacent to each other.

11. A method of manufacturing a display device, the method comprising:
providing a substrate including a display area including sub-pixels, and a non-display area disposed adjacent to the display area;
forming a first electrode on the substrate;
applying an insulating layer to overlap the first electrode;
forming a second electrode on the insulating layer;
exposing at least a portion of the first electrode by patterning the insulating layer;
forming a light emitting structure on the first electrode and the second electrode in the display area; and
forming a third electrode on the light emitting structure.

12. The method according to claim 11, wherein the third electrode is formed on the second electrode in at least a portion of the non-display area.

13. The method according to claim 12, wherein the third electrode electrically contacts the second electrode in the at least the portion of the non-display area.

14. The method according to claim 12, wherein the third electrode is electrically connected to the first electrode in the at least the portion of the non-display area.

15. The method according to claim 12, wherein the third electrode is electrically connected to a conductive pattern disposed under the first electrode in the at least the portion of the non-display area.

16. The method according to claim 12, wherein the third electrode is formed on the light emitting structure in the display area and disposed on the insulating layer in the at least the portion of the non-display area.

17. The method according to claim 11, wherein
the light emitting structure fills an opening of the insulating layer exposing the at least the portion of the first electrode, and
the light emitting structure is entirely disposed on the insulating layer in the display area.

18. The method according to claim 11, wherein the light emitting structure comprises:
a first light emitting unit;
a second light emitting unit disposed on the first light emitting unit; and
a connection layer disposed between the first light emitting unit and the second light emitting unit and electrically connecting the first light emitting unit and the second light emitting unit.

19. The method according to claim 11, wherein a voltage applied to the second electrode is less than a voltage of the first electrode at a lowest grayscale.

20. The method according to claim 11, wherein
the second electrode is disposed in a boundary area between at least two of the sub-pixels, and
the at least two of the sub-pixels are adjacent to each other.
